(19) United States
(12) Patent Application Publication
(10) Pub. No.: US 2011/0037044 A1
(43) Pub. Date: Feb. 17, 2011

(54) INFORMATION RECORDING DEVICE AND INFORMATION RECORDING/REPRODUCTION SYSTEM INCLUDING THE SAME

(75) Inventors: Takeshi Araki, Tokyo (JP); Takayuki Tsukamoto, Kanagawa (JP); Takeshi Yamaguchi, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, TOKYO (JP)

(21) Appl. No.: 12/921,471

(22) PCT Filed: Mar. 10, 2009
(86) PCT No.: PCT/JP09/54978

§ 371 Date: Sep. 8, 2010

(30) Foreign Application Priority Data
Mar. 13, 2008 (JP) 2008-064671

(51) Int. Cl. H01L 45/00

(52) U.S. Cl. 257/2; 257/E45.001

(57) ABSTRACT

This disclosure provides an information recording device for use in a non-volatile information recording/reproduction system having a high recording density, the device including a resistive material having less phase separation or the like during switching. This disclosure also provides an information recording/reproduction system including the device. This disclosure provides an information recording device including: a pair of electrodes; and a recording layer between the electrodes, the recording layer recording information by its resistance change, the recording layer including at least one of (a) M₃O_{z} and (b) AₓM₃_{_{—}}ₓ0_{z} as a main component, in (a) and (b), z being a value representing oxygen deficiency from z=4.5, and in (b), x satisfying 0.00<x≦0.03. This disclosure also provides an information recording/reproduction system including the device.

### TECHNICAL FIELD

The present invention relates to an information recording device for use in an information recording/reproduction system having a high recording density and an information recording/reproduction system including the same.

### BACKGROUND ART

Compact mobile devices have recently become prevalent worldwide. High speed information transmission networks have concurrently made significant progress. Demands for compact and large capacity non-volatile memories have thus been rapidly enlarged. Particularly, NAND flash memories and compact HDDs (hard disk drives) have rapidly increased their record densities and been used in a variety of applications including the mobile music market, mobile game recording memories, personal computer storage devices, and others. A huge market of several hundred millions has thus been formed.

The huge market is formed mainly because the capacities of both the recording media have been steadily increased. As the teachings of the Moore's law in which the capacity increases almost every year and doubles every two years, the capacity has been developed surprisingly rapidly.

The rapid capacity increase has reduced the price per unit record capacity, which is very desirable for users. It has been said, however, that the capacity will continuously increase and thus the price per unit record capacity will not stop decreasing. The technologies are memories.

Unfortunately, it has recently been said that the micro-fabrication and densification of both the recording media reach the limit. This is because it becomes concerned that the difficulty of controlling the microfabrication process will reduce the yield, which may, conversely, increase the cost per unit record capacity.

Substances and mechanisms different from the silicon-based semiconductors have recently been used to energetically attempt to break through the limit of the conventional microfabrication technologies. These semiconductor memories are called post NAND memories. Their importance is easily imagined from the fact that large enterprises in each country and their associated venture companies concentrate on development of the key technologies. In the post NAND memories, a variety of solid state property changes have been tried to provide memory operations.

A variety of memories have been proposed for the post NAND memories including those using the phase change to provide the record device, those using the magnetic change, those using the ferroelectric, and those using the resistance change. One memory that is expected to have less power consumption and drastically faster write/read speed than the conventional memories by microfabrication is a resistive memory, the so-called resistive random access memory (ReRAM).

The minimum elements of ReRAMs are the top and bottom electrodes and a resistive material therebetween. Most of the currently reported experiments use expensive platinum as the top and bottom electrodes.

The resistive materials include simple oxides such as NiO and CoO, non-oxides such as ZnCaS, and complex oxides such as Pr_{0.7}Ca_{0.3}MnO₃ that have the perovskite structure well known in the superconducting materials. It is true that the switching mechanisms for these materials are not well known.

The resistance change phenomenon is not well clarified mainly because the changes seem to occur in very small regions. It is difficult to acquire the X-ray diffraction data of the changes in the region supposed to be about 10 nm unless the materials have very good orientation or the like. The clarification of the mechanism thus encounters unprecedented difficulties in the research and development.

To clarify the phenomenon, a variety of models have been proposed. But they are difficult to verify and none of them seem to be most likely. The presence of a large number of models also proves that no models are most likely.

Although the switching mechanism of the ReRAM has not been completely clarified, the most recent conference presentations have showed significantly improved number of switchings. The most recent presentations have reported ten million switchings of bipolar operations. This result is strongly expected to provide the future post NAND.

A large number of ten million switching operations will cause durability issues with a variety of parts. Most of all, the issues include oxidation and reduction of electrodes, the stability of the ReRAM materials, the diode degradation due to heat generation or the like. Because the post NAND memories use materials different from those in previous NAND flash memories, material degradation over time or the like is expected to become problems depending on the strong chemicals or conditions used in the processes.

Unlike the bipolar operations, the unipolar operations always maintain one electrode at the oxidation or reduction state. The unipolar operations are thus considered advantageous in view of the electrode durability or the like. Another significant concern may relate to, however, the durability of RAM materials themselves.

The reported materials for switchings in the unipolar operations as the ReRAM materials include AB₂O₄ spinel oxide or the like. Complex oxides having a perovskite structure such as Pr_{0.7}Ca_{0.3}MnOₓ are also reported (JPH 8-133894). Such complex oxide based materials may disadvantageously decrease the number of switchings if the ReRAM materials undergo phase separation or the like due to heat generation or electric energy.

Although ReRAM materials including the complex oxides are expected to encounter disadvantages, it is not clearly known at the moment what mechanism or system causes the changes between the low resistance and the high resistance. The most recent conferences discuss whether the changes are caused by ion movements or shot key barriers, or whether electric energy or heat energy contributes to the changes.

It is difficult to conclude the discussions because it is supposed that the changes occur in a small region of about 10 nm length and because it is often presented at conferences that not-oriented materials also provide the switchings. It is difficult to measure the poorly-oriented substances in a small region by XRD. The clarification of the switching mechanism has thus not proceeded well.

Completion of products without understanding the switching mechanism will make it very difficult to correspond to problems. It is thus necessary to understand the switching mechanism. Even though the details of the switching mechanism are not obviously known from currently available information, it is still necessary to experimentally find at least the condition for the stable operations and to suppose a corresponding mechanism in order to ensure the region in the material composition to allow for the stable operations.

In addition, although the switching characteristics have been reported on the metal oxides other than the complex oxides, it is necessary to find materials and conditions or the like for the good switching characteristics to provide practical use in future.

It is on object of the present invention to provide an information recording device for use in a non-volatile information recording/reproduction system having a high recording density, the device including a resistive material having less phase separation or the like during switching, and also to provide an information recording/reproduction system including the device.

### DISCLOSURE OF INVENTION

To achieve the above objects, a first aspect of the present invention is an information recording device including: a pair of electrodes; and a recording layer between the electrodes, the recording layer recording information by its resistance change, the recording layer including at least one of (a) M₃O_{z} and (b) AₓM₃₋ₓO_{z} as a main component, and in (b), x satisfying 0.00<x≦0.03.

A second aspect of the present invention is an information recording device including: a pair of electrodes; and a recording layer between the electrodes, the recording layer recording information by its resistance change, the recording layer including AₓM₃₋ₓO_{z} as a main component, and x satisfying 0.15≦x≦0.90.

A third aspect of the present invention is an information recording device including: a pair of electrodes; and a recording layer between the electrodes, the recording layer recording information by its resistance change, the recording layer including at least one of (a) MO_{z} and (b) B_{y}M_{1-y}O_{z} as a main component, and in (b), y satisfying 0.00<x≦0.03.

A fourth aspect of the present invention is an information recording/reproduction system including any of the above information recording devices.

Thus, the present invention provides an information recording device for use in a non-volatile information recording/reproduction system having a high recording density, the device including a resistive material having less phase separation or the like during switching, and also provides an information recording/reproduction system including the device.

### BRIEF DESCRIPTION OF THE DRAWINGS

FIG. 1 is a schematic diagram of elements of an information recording device according to the present invention;

FIG. 2 is a profile of Zn composition ratio versus switching number;

FIG. 3 is a profile of observed isolated metal oxide amount versus Zn composition ratio; and

FIG. 4 shows phase identification of Mn₂O₃ and Mn₃O₄ by 2θ/ω measurement.

### BEST MODE FOR CARRYING OUT THE INVENTION

First, an information recording device according to a first aspect and a second aspect of the present invention will be described below. In an information recording device according to the first and second aspects, A is preferably at least one of Zn, Cd, and Hg, and more preferably, Zn. M is preferably at least one of Cr, Mn, Fe, Co, and Ni, and more preferably, Mn. According to the first and second aspects of the present invention, the combination of A and M in (a) M₃O_{z} and (b) AₓM₃₋ₓO_{z} is preferably Zn and Mn, i.e., the compositions are preferably (a) Mn₃O_{z} and (b) ZnₓMn₃₋ₓO_{z}, and more preferably, (a) Mn₃O, and (b) ZnₓMn₃₋ₓO_{z} for 0.00<x≦0.03.

In an information recording device according to the first and second aspects, z is preferably a value representing oxygen deficiency from z=4.5 and is preferably in the range representing at least a certain amount of oxygen deficiency. Specifically, it is preferable that 80% or more of the crystal of the composition has a value of 3.35≦z≦4.41 and the entire composition has an average of 3.65≦z≦4.20. The value of Z may be adjusted by decreasing the oxygen partial pressure or increasing the substrate temperature during deposition.

In an information recording device according to the first and second aspects, the value of x may be adjusted by changing the target composition in PLD or sputtering for deposition on an electrode. For example, powders of Mn oxide and Zn oxide are simply mixed as uniformly as possible and sintered to form a target. Materials may be deposited by laser plume or sputtering from the target. The value of x may be adjusted to an arbitrary value to provide desired Mn₃O_{z} or ZnₓMn₃₋ₓO_{z}.

In a deposition process such as MOCVD, a raw material of the above composition for deposition may be prepared to adjust x to an arbitrary value to provide a desired information recording device according to the first and second aspects of the present invention.

In a chemical solution process such as MOD, if metal alkoxide can be uniformly dispersed in the raw material solution without precipitation, the value of x may be adjusted to an arbitrary value to provide a desired information recording device according to the first and second aspects of the present invention. This process uses precipitation from solution and thus often maintains the nano level uniformity. This process is one of the processes that may most easily provide uniform composition materials.

According to an information recording device in the first and second aspects of the present invention, in AₓM₃₋ₓO_{z} as a main component of the recording layer, 0.00≦x≦0.03 and 0.15≦x≦0.90 may provide stable operation without any phase separation during a number of switchings.

In the x range except the first region of 0.00≦x≦0.03 and the second region of 0.15≦x≦0.90, the following phases are observed. For 0.03<x<0.15, nano-microcrystals of Mn₂O₃ and Mn₃O₄ are observed, for example, by high-resolution TEM. For the region of 0.90<x≦3.00, more nano-microcrystals of ZnO are observed, for example, as x increases.

In the regions except the first and second regions, a generally smaller number of switchings are observed. This is considered to be because the switchings cause some internal physical phenomena that precipitate the simple metal oxide, thus inhibiting switchings.

In the first and second regions, in the observation of the information recording layer with high-resolution TEM, the simple oxide is little detected. This result is a combination of, for example, a result at about 1200° C. and a result at about 600° C. on the phase diagram of ZnₓMn₃₋ₓO₄. Specifically, Mn-based oxide is precipitated in the former and ZnO is isolated in the latter.

With respect to the above phenomena, the ZnO precipitation may be described by an assumption in which heat contributes to the reset phenomenon that requires much more energy than at set, although this assumption is not proven. The phase diagram indicates temperature increase up to about 600° C. It is considered that in a number of switchings during which ZnO is precipitated, the precipitation inhibits switchings, thus decreasing the number of switchings.

The Mn oxide precipitation may be interpreted as follows. The materials have a thermal history in which they are overheated at reset and then cooled, thus discharging MnO during the cooling process. It is considered that in the first region where x is very small and the phenomenon does not occur, the switching operations are stable. Additionally, it is desired to have oxygen deficiency having x of 3.35 to 4.41 with respect to x=4.5.

An information recording device according to a third aspect of the present invention will be described. In an information recording device according to the third aspect, M is preferably Ce, and at least one of Zr and Ti, and more preferably, Ce or Zr. B is preferably at least one of metal elements similar to Ce, such as Sc, Y, and the lanthanoid elements except Ce. Particularly, the lanthanoid elements each have a trivalent combined state like Ce and similar atomic weights and similar chemical character. It is thus very difficult to purify them. It is known that the lanthanoid elements easily have the above elements mixed therein up to around three atom %.

In an information recording device according to the third aspect, z is preferably a value representing oxygen deficiency from z=2 and is preferably in the range representing at least a certain amount of oxygen deficiency. Specifically, it is preferable that 80% or more of the crystal of the composition has a value of 1.50≦z≦1.98 and the entire recording layer has an average of 1.70≦z≦1.95. The value of Z may be adjusted by decreasing the oxygen partial pressure or increasing the substrate temperature during deposition.

With respect to CeO_{z}, a CeO₂ target is used and a deposition process such as PLD is used for deposition, and the substrate temperature and the oxygen partial pressure during deposition or the like may be used to adjust y to an arbitrary value to provide a desired information recording device according to the third aspect of the present invention.

In a deposition process such as MOCVD, a raw material of the above composition for deposition may be prepared to adjust y to an arbitrary value to provide a desired information recording device according to the third aspect of the present invention.

In a chemical solution process such as MOD, if metal alkoxide can be uniformly dispersed in the raw material solution without precipitation, the value of x may be adjusted to an arbitrary value to provide a desired information recording device according to the third aspect of the present invention. This process is called the ex situ process in which the deposition and the thermal treatment are completely separated. The ex situ process may accurately set the value of y by adjusting the firing temperature and the oxygen partial pressure of the thermal treatment conditions and the oxygen annealing starting temperature.

A number of switching operations may also be performed in an information recording layer material that includes CeO_{z} as the principal substance. Ce is a lanthanoid element and so it often has different lanthanoid elements mixed therein up to three atom % of Zr or Ti also shows deposition and switching effects like CeO_{z}.

### EXAMPLES

With reference to the accompanying drawings, examples of the information recording device according to the present invention will be described in more detail.

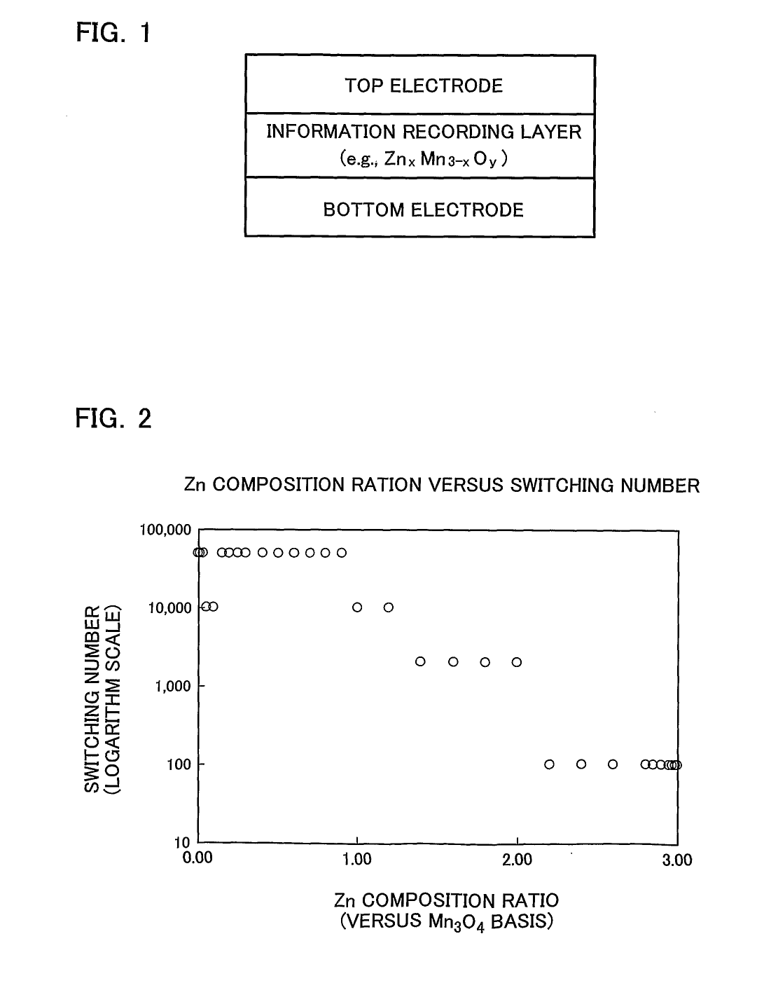

FIG. 1 shows an example configuration of an information recording device according to the present invention. The device includes, from the bottom up, a bottom electrode including TiN, an information recording layer including a material such as ZnₓMn₃₋ₓO_{z}, and a top electrode including Pt. Note that for ZnₓMn₃₋ₓO_{z} in the present invention, z is around 4.4 and x is only in a first region of 0.00≦x≦0.03 or a second region of 0.15≦x≦0.90. Although FIG. 1 shows only a ZnMnO based compound, other compounds may also be used including Mn₂O₃, CeO₂, ZrO₂, and oxygen deficient phases thereof.

FIG. 2 shows the results of the switching tests using the information recording layer of ZnₓMn₃₋ₓO_{z}. The evaluation was done using four regions: a region of 50000 or more switchings, a region of 10000 to 50000 switchings, a region of 2000 to 10000 switchings, and a region of less than 2000 switchings. The four regions are represented by the plots, for example the region of 50000 or more switching at 50000, in the graph. Note that owing to the limited experimental time, the samples having 50000 or more switchings are represented by the plots at 50000.

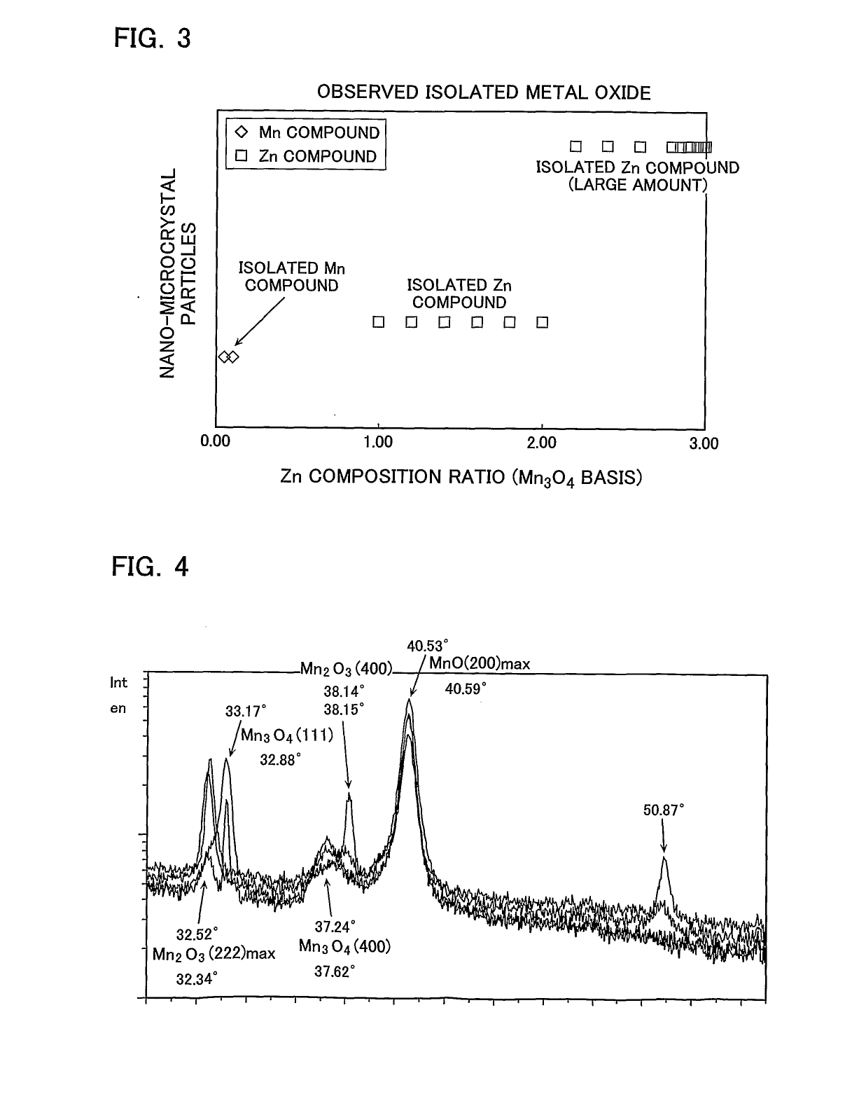

FIG. 3 shows compositions where the phase separations were observed in the information recording layer of ZnₓMn₃₋ₓO_{z} by high-resolution TEM. Particularly, FIG. 3 shows regions where Mn oxide was observed and where ZnO was observed.

### Experiment Example 1

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

A resistive layer (recording layer) was deposited by the pulse laser deposition (PLD). The targets for deposition were formed by the general sintering process. The targets had different compositions. The raw material powders were mixed to provide different compositions of Zn:Mn with the total composition of 3. Mixtures were held at temperatures suitable for sintering at respective compositions for a sufficient time to form targets.

In this way, the targets were formed to have different compositions with an amount of Zn of 0 to 3. A target with Zn of 0.15, for example, is described as Tz(0.15). The prepared targets were Tz(0.00), Tz(0.01), Tz(0.03), Tz(0.05), Tz(0.10), Tz(0.15), Tz(0.20), Tz(0.25), Tz(0.30), Tz(0.40), Tz(0.50), Tz(0.60), Tz(0.70), Tz(0.80), Tz(0.90), Tz(1.00), Tz(1.20), Tz(1.40), Tz(1.60), Tz(1.80), Tz(2.00), Tz(2.20), Tz(2.40), Tz(2.60), Tz(2.80), Tz(2.85), Tz(2.90), Tz(2.95), Tz(2.97), Tz(2.99), and Tz(3.00).

All of the targets were used. A substrate with TiN/W/Si layers deposited thereon was heated at 500° C. in a vacuum chamber. A film was then deposited on the substrate at an oxygen pressure of 10e⁻² Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film from a target of Tz(0.15), as 1RP(0.15) [which means an ReRAM material in the experiment example 1, in the pre-state, with Zn of 0.15].

All of the samples were placed again in the vacuum chamber. A Pt layer was sputtered on top of each sample with a mask thereon to deposit a cylindrical Pt pad having a diameter of 50 micron. Each resulting sample is described, for example, as 1R(0.15) for a film with a Pt pad derived from Tz(0.15).

Each resulting electrode's surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

The samples having 50000 or more successive switchings are 1R(0.00), 1R(0.01), 1R(0.03), 1R(0.15), 1R(0.20), 1R(0.25), 1R(0.30), 1R(0.40), 1R(0.50), 1R(0.60), 1R(0.70), 1R(0.80), and 1R(0.90).

The samples having 10000 to 50000 switchings are, 1R(0.05), 1R(0.10), 1R(1.00), 1R(1.20). The samples having 2000 to 10000 switchings are 1R(1.40), 1R(1.60), 1R(1.90), and 1R(2.00). All of the other samples have less than 2000 switchings.

A sufficient number of switchings were observed in the separate regions of 0.00≦x≦0.03 and 0.15≦x≦0.90. It was also observed that the regions for more amount of Zn tended to show less number of switchings.

### Experiment Example 2

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer (recording layer) was deposited by the pulse laser deposition (PLD). The targets for deposition were formed by the general sintering process. The targets had different compositions. The raw material powders were mixed to provide different compositions of Zn:Mn with the total composition of 3. Mixtures were held at temperatures suitable for sintering at respective compositions for a sufficient time to form targets.

In this way, the targets were formed to have different compositions with an amount of Zn of 0 to 3. A target with Zn of 0.15, for example, is described as Tz(0.15). The prepared targets were Tz(0.00), Tz(0.01), Tz(0.03), Tz(0.05), Tz(0.10), Tz(0.15), Tz(0.20), Tz(0.25), Tz(0.30), Tz(0.40), Tz(0.50), Tz(0.60), Tz(0.70), Tz(0.80), Tz(0.90), Tz(1.00), Tz(1.20), Tz(1.40), Tz(1.60), Tz(1.80), Tz(2.00), Tz(2.20), Tz(2.40), Tz(2.60), Tz(2.80), Tz(2.85), Tz(2.90), Tz(2.95), Tz(2.97), Tz(2.99), and Tz(3.00).

All of the targets were used. A substrate with TiN/W/Si layers deposited thereon was heated at 500° C. in a vacuum chamber. A film was then deposited on the substrate at an oxygen pressure of 10e⁻² Pa by the PLD process using a laser power of 130 mJ/mm². The deposition time was controlled to have a film thickness of about 30 nm. Samples having substrates with resistive materials deposited thereon were thus provided. Each resulting sample is described, for example, for a film from a target of Tz(0.15), as 2RP(0.15) [which means an ReRAM material in the experiment example 2, in the pre-state, with Zn of 0.15].

All of the samples were placed again in the vacuum chamber. A Pt layer was sputtered on top of each sample with a mask thereon to deposit a cylindrical Pt pad having a diameter of 100 micron. Each resulting sample is described as, for example, 2R(0.15) for a film with a Pt pad derived from Tz(0.15).

Each resulting electrode's surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings of 10000 were performed for each sample.

In all samples, a plan-view TEM observation was performed in a horizontal direction in a plane in parallel with the substrate, the plane being at about 15 nm apart from the substrate, the distance being about half the thickness of the resistive material film. The samples were observed at the highest magnification possible and then checked for Mn oxide and Zn compound by EDS analysis. It was possible to identify ZnO as a compound, because it formed nano-microcrystals. The substance that was considered to be Mn oxide, however, had low orientation and thus was sensed only as Mn oxide.

Of the resulting samples, layers considered to be the nano-microcrystals or the Mn phase separations were hardly detected in 2R(0.00), 2R(0.01), 2R(0.03), 2R(0.15), 2R(0.20), 2R(0.25), 2R(0.30), 2R(0.40), 2R(0.50), 2R(0.60), 2R(0.70), 2R(0.80), 2R(0.90).

A small amount of Mn oxide was detected in 2R(0.05) and 2R(0.10). A small amount of ZnO was detected in 2R(1.00), 2R(1.20), 2R(1.40), 2R(1.60), 2R(1.80), and 2R(2.00). A large amount of ZnO was detected in the other samples. The term of “a small amount” means that in a TEM observed-area of a 300 nm square, only five or less nano-microcrystals were observed to have a length of 5 nm or more.

It was found that the results of the plan-view TEM observations were correlated with the switching characteristics shown in the experiment example 1. It is supposed that the switching phenomenon was adversely affected by the different isolated substances because the switching characteristics tended to reduce for the different isolated substances.

Thus, the experiment examples 1 and 2 showed that in ZnₓMn₃₋ₓO_{z}, which is a resistive recording material used in the information recording device according to the present invention, only a specific value of x increased the number of switchings. The regions included the first region of 0.00≦x≦0.03 and the second region of 0.15≦x≦0.90.

The principle in which a large number of stable switching operations may occur is considered to be the prevention of the isolated metal oxide. At reset, due to the heat generation and the slow cooling, even at a constant composition on a phase diagram, the switchings are considered to be largely affected by the isolated metal oxide that is considered to be formed under the reached temperature.

### Experiment Example 3

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer (recording layer) was deposited by the pulse laser deposition (PLD). The targets for deposition were formed by the general sintering process. Only a target of Mn₂O₃ was used. This was because a previous document relating to the Zn—Mn—O based complex oxide (S. Mogck, B. J. Kooi, and J. Th. M. De Hosson, “Tailoring of misfit along interfaces between, ZnₓMn₃₋ₓO₄ and Ag,” Acta Materialia vol. 52, (2004) 5845-5851) reported that the oxide forms an oriented structure at ambient ratios and easily discharges ZnO. Even if, therefore, signals are obtained from high-resolution TEM observation or XRD measurement, it is considered to be difficult to suppose what they reflect.

The Mn₂O₃ target was used. A substrate with TiN/W/Si layers deposited thereon was heated at 200, 300, 400, 500, and 600° C. in a vacuum chamber. A film was then deposited on the substrate at an oxygen pressure of 1×10E⁺⁰ Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film provided on a substrate heated at 200° C., as 3RPT(200) (which means an ReRAM material in the experiment example 3, in the pre-state, with a temperature of 200° C.).

All of the samples were placed again in the vacuum chamber. A Pt layer was sputtered on top of each sample with a mask thereon to deposit a cylindrical Pt pad having a diameter of 50 micron. The resulting sample is described here, for example, as 3RT(200) for a film with a Pt pad derived from 3RPT(200).

The resulting 3RT(200), 3RT(300), 3RT(400), 3RT(500), and 3RT(600) were subject to phase identification by XRD measurement. The possibility of the reaction between the TiN layer and Mn oxide layer during the PLD deposition was supposed on the analogy of other systems. Ba and the Gd₂Zr₂O₇ interlayer may react at 730° C. or more. Ba is one of the two group elements and easily movable in the superconducting films. The Gd₂Zr₂O₇ interlayer may withstand diffusion of a variety of substances. The combination of MnO based materials for the ReRAM and TiN is considered to be further stable because it includes no reactive element like Ba. It is supposed that little reaction of the combination occurs under the environment in which the maximum temperature is only 600° C.

Each of the 3RT(200), 3RT(300), 3RT(400), 3RT(500), and 3RT(600) films has significantly small thickness of 20 nm. The XRD measurement through a concentrating optical system was thus used to identify their phases. The results showed that as shown in FIG. 4, two main peaks considered as the largest peaks were observed at 2θ of about 32 to 33 degrees, although the peaks were weak. The peaks in the peripheral area were the only changes observed.

The presence of the peak showed that not all of at least the 20 nm material was amorphous. Taking into consideration of the fact that the phase depended on the deposition condition and the subsequent ICP measurements showed almost the same amount of substance, it may be supposed that most of the portions representing no crystalline are amorphous layers.

With respect to the fact that the measurements showed only the main peaks, it may be due to a ultra-thin film of 20 nm thickness including the mixture of the amorphous layer and the nano-microcrystal layer. This is consistent with the measurements in other fields. The peaks had relatively wide half widths, meaning that diffraction in different directions reduces the XRD peaks. It is thus reasonably supposed that other phases will probably not appear.

In addition, as described above, the Mn oxide and the TiN layer hardly react at a low temperature of 600° C. For the PLD deposition of MnO, therefore, only the compounds of different Mn valences may be assumed to cover all substances.

The XRD results showed that the peaks of Mn₃O₄ increased as the deposition temperature increased and the peaks of Mn₂O₃ increased as the deposition temperature decreased. The sample of 3RT(200) was measured by XPS to provide the value of z of Mn₃O_{z} as an average of the entire film. The value was 4.32. The samples of 3RT(300), 3RT(400), 3RT(500), and 3RT(600) showed 4.08, 3.93, 3.81, and 3.65, respectively. It was reported that MnO based oxide became more oxygen deficient as it was deposited at higher temperatures. This phenomena is considered to appear in the above measurements.

A Pt electrode was deposited on each sample surface. Each surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

Five samples of 3RT(200) were measured. They showed the maximum number of switchings of 20000 and showed unstable behaviors between the samples. Every other sample had the maximum number of switchings over 50000. Particularly, the samples of 3RT(400) and 3RT(500) stably showed switchings over 50000 with a probability of 80% or more.

Because XRD showed the presence of the nano-microcrystals of MnO, the high-resolution TEM was used to observe the structure of MnO. The results showed that for the samples of 3RT(300), 3RT(400), 3RT(500), and 3RT(600) representing a sufficient number of switchings of 50000 or more, z representing the local oxygen deficiency with respect to the distance from Mn—O had a value of 3.35 to 4.41. The TEM image showed that 80% or more of the nano micro crystals had those z values. It is supposed that the oxygen deficiency amount impairs the insulator nature of the nano-microcrystal and reduces its resistance. A specific oxygen deficiency amount showed the stable switchings. It is thus considered that the series of experiments showed the oxygen deficiency range for the first time that is suitable for the future information recording/reproduction device and the application therefor.

### Experiment Example 4

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer was deposited by the pulse laser deposition (PLD). The targets for deposition were formed by the general sintering process. Only the target of Mn₂O₃ was used.

The Mn₂O₃ target was used. A substrate with TiN/W/Si layers deposited thereon was heated at 400° C. in a vacuum chamber. A film was then deposited on the substrate at oxygen partial pressures of 1×10E⁻², 1×10E⁻¹, 1×10E⁺⁰, 1×10E⁺¹, and 1×10E⁺² Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film deposited at an oxygen partial pressure of 1×10E⁻² Pa, as 4RPO(−2) (which means an ReRAM material in the experiment example 4, in the pre-state, with an oxygen partial pressure 1E⁻² Pa).

All of the samples were placed again in the vacuum chamber. A Pt layer was sputtered on top of each sample with a mask thereon to deposit a cylindrical Pt pad having a diameter of 50 micron. The resulting sample is described here, for example, as 4RO(−2) for a film with a Pt pad derived from 4RPO(−2).

The resulting 4RO(−2), 4RO(−1), 4RO(0), 4RO(1), and 4RO(2) were subject to phase identification by XRD measurement. The possibility of the reaction of the TiN layer and Mn oxide layer during the PLD deposition was supposed as follows. As described above, Ba, which is one of the two group elements, and Gd₂Zr₂O₇ interlayer, which may withstand diffusion of a variety of substances, may react at 730° C. or more. The combination of MnO based materials for the ReRAM and TiN is considered to be further stable. It is supposed that during the PLD deposition at up to 400° C., little chemical reaction occurs between the ReRAM materials and the TiN substrate.

Each of the 4RO(−2), 4RO(−1), 4RO(0), 4RO(1), and 4RO(2) films has significantly small thickness of 20 nm. XRD measurement through a concentrating optical system was thus used to identify their phases. Results showed that two main peaks considered as the highest peaks were observed at 28 of about 32 to 33 degrees, although the peaks were weak. The peaks in the peripheral area were the only changes observed.

The presence of the peak showed that not all of at least the 20 nm material was amorphous. Taking into consideration of the fact that the phase depended on the deposition condition and the subsequent ICP measurements showed almost the same amount of substance or the like, it may be supposed that most of the portions representing no crystallinity are amorphous layers.

With respect to the fact that the measurements showed only the main peaks, it may be due to a ultra-thin film of 20 nm thickness including the mixture of the amorphous layer and the nano-microcrystal layer. This is consistent with the measurements in other fields. The peaks have relatively wide half widths, meaning that diffraction in different directions reduces the XRD peaks. It is thus reasonably supposed that other phases will not be observed.

In addition, as described above, the Mn oxide and the TiN layer hardly react at a low temperature of 400° C. For the PLD deposition of MnO, therefore, only the compounds of different Mn valences may be assumed to cover all substances.

The XRD results showed that the peaks of Mn₃O₄ increased as the oxygen partial pressure increased and the peaks of Mn₃O₄ increased as the oxygen partial pressure decreased. The samples of 4RO(2) and 4RO(1) were measured by XPS to provide the value of z of Mn₃O_{z} as an average of the entire film. The values were 4.47 and 4.23, respectively. In addition, only these two samples each showed a circular different phase having a diameter of about 0.5 mm on the film surface. The samples of 4RO(−2), 4RO(−1), and 4RO(0) showed 4.10, 3.93, and 3.85, respectively. It was reported that a phase diagram shows that MnO based oxide becomes more oxygen deficient under lower oxygen partial pressures. This phenomena is considered to appear in the above measurements.

A Pt electrode was deposited on each sample surface. Each surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

The samples of 4RO(2) and 4RO(1) showed the maximum number of switchings of about 5000 and 20000, respectively. They also showed unstable behaviors between the samples. The other samples all showed the maximum number of switchings over 50000.

Because XRD showed the presence of the nano-microcrystals of MnO, the high-resolution TEM was used to observe the structure of MnO. The results showed that for the samples of 4RO(−2), 4RO(−1), and 4RO(0) representing a sufficient number of switchings of 50000 or more, z representing the local oxygen deficiency with respect to the distance from Mn—O had a value of 3.79 to 4.23. It is supposed that the oxygen deficiency amount impairs the insulator nature of the nano-microcrystal and reduces its resistance. A specific oxygen deficiency amount showed the stable switchings. It is thus expected that the oxygen deficiency range will provide the future information recording/reproduction device and the application therefor.

Thus, the experiment examples 3 and 4 showed that ZnₓMn₃₋ₓO_{z} forms complex oxides and takes a lattice structure at any compositions, and it is thus difficult to measure the oxygen deficiency amount of the ZnₓMn₃₋ₓO_{z}, but the relationship between the switchings and the z amount was found for the deposition of Mn₃O_{z}.

Particularly, the experiment examples 3 and 4 showed that the recording layer having a composition of Mn₃O_{z} locally having 3.35≦z≦4.41 may improve the number of switchings.

The experiment examples 3 and 4 also showed that the recording layer having an average value of 3.65≦z≦4.20 in Mn₃O_{z} may improve the number of switchings and the deposition in this region may provide good switching characteristics.

### Experiment Example 5

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer (recording layer) was deposited by the pulse laser deposition (PLD). The targets for deposition were formed by the general sintering process. The target of CeO₂ was used. The lanthanoid target easily has a different type of lanthanoid elements having similar chemistry mixed therein. Up to about three atom % of lanthanoid elements may replace Ce. In the experiment example 5, however, about one atom % of mixture ratio was observed by ICP.

The CeO₂ target was used. A substrate with TiN/W/Si layers deposited thereon was heated at 200, 300, 400, 500, and 600° C. in a vacuum chamber. A film was then deposited on the substrate at an oxygen pressure of 1×10E⁺⁰ Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film provided on a substrate heated at 200° C., as 5RPT(200) (which means an ReRAM material in the experiment example 5, in the pre-state, with a temperature of 200° C.).

All of the samples were placed again in the vacuum chamber. A Pt layer was sputtered on top of each sample with a mask thereon to deposit a cylindrical Pt pad having a diameter of 50 micron. The resulting sample is described here, for example, as 5RT(200) for a film with a Pt pad derived from 5RPT(200).

The resulting 5RT(200), 5RT(300), 5RT(400), 5RT(500), and 5RT(600) were subject to phase identification by XRD measurement. The XRD method measured the samples through a concentrating optical system although the samples were thin films requiring strict setting of the height.

The measurement results showed that the (004) peak supposed to appear at 2θ of about 69 degrees overlapped with the Si single crystal peak and was not separated, but a wide half-width peak, which was considered to be (002) peak, was observed near 33 degrees. The peak shifted slightly towards higher temperatures as the deposition temperature increased. It is considered that CeO₂ including oxygen deficiency was deposited.

The high-resolution TEM analyzed the oxygen deficiency amount of the 5RT(600) sample. The measured amount and the peak shifts in the XRD measurement were used to calculate the amount of bound oxygen. The results showed that the samples of 5RT(200), 5RT(300), 5RT(400), 5RT(500), and 5RT(600) showed 1.99, 1.96, 1.91, 1.82, and 1.70, respectively. The values were small but clearly showed more oxygen deficient at higher temperatures:

A Pt electrode was deposited on each sample surface. Each surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

The samples of 5RT(200) showed the maximum number of switchings of 35000 and also showed unstable behaviors between five samples. Some samples showed zero switchings. The other samples all showed the maximum number of switchings over 50000. Particularly, the samples of 5RT(500) and 5RT(600) stably showed switchings over 50000 with a probability of 80% or more when the individual deposited Pt pads were measured.

Because XRD showed the presence of nano-microcrystals of CeO₂, the high-resolution TEM was used to observe the structure of CeO₂. The results showed that the samples of 5RT(300), 5RT(400), 5RT(500), and 5RT(600) representing a sufficient number of switchings of 50000 or more had z of 1.50 to 1.98 for CeO_{z}. It is supposed that the oxygen deficiency amount impairs the insulator nature of the nano-microcrystal and reduces its resistance. A specific oxygen deficiency amount showed the stable switchings. It is thus considered that the series of experiments showed the oxygen deficiency range for the first time that is suitable for the future information recording/reproduction device and the application therefor.

### Experiment Example 6

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer (recording layer) was deposited by the pulse laser deposition (PLD). The targets for deposition were formed by the general sintering process. The target of CeO₂ was used.

The CeO₂ target was used. A substrate with TiN/W/Si layers deposited thereon was heated at 400° C. in a vacuum chamber. A film was then deposited on the substrate at oxygen partial pressures of 1×10E⁻², 1×10E⁻¹, 1×10E⁺⁰, 1×10E⁺¹, and 1×10E⁺² Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film deposited at an oxygen partial pressure of 1×10E⁻² Pa, as 6RPO(−2) (which means an ReRAM material in the experiment example 6, in the pre-state, with an oxygen partial pressure 1×10E⁻² Pa).

All of the samples were placed again in the vacuum chamber. A Pt layer was sputtered on top of each sample with a mask thereon to deposit a cylindrical Pt pad having a diameter of 50 micron. The resulting sample is described here, for example, as 6RO(−2) for a film with a Pt pad derived from 6RPO(−2).

The resulting 6RO(−2), 6RO(−1), 6RO(0), 6RO(1), and 6RO(2) were subject to phase identification by XRD measurement. The possibility of the reaction between the TiN layer and Ce oxide layer during the PLD deposition was supposed on the analogy of other systems. Ba and the CeO₂ interlayer may react at 730° C. or more. Ba is one of the two group elements and easily movable in the superconducting films. The CeO₂ interlayer may withstand diffusion of a variety of substances. The combination of Ce, which is one of Ce based materials for the ReRAM, and TiN is considered to be further stable because it includes no Ba. It is supposed that little reaction of the combination occurs under the environment in which the maximum temperature is only 400° C.

Each of the 6RO(−2), 6RO(−1), 6RO(0), 6RO(1), and 6RO(2) films has significantly small thickness of 20 nm. The XRD measurement through a concentrating optical system was thus used to identify their phases. The results showed that two main peaks considered to be the largest peaks were observed at 20 of about 33 degrees, although they were weak. The peaks in the peripheral area were the only changes observed. Little difference was observed between the peak positions.

The presence of the peak showed that not all of at least the 20 nm material was amorphous. Taking into consideration of the fact that changing the phase depended on the deposition condition and the subsequent ICP measurements showed almost the same amount of substance, it may be supposed that most of the portions representing no crystallinity are amorphous layers.

With respect to the fact that the measurements showed only the main peaks, it may be due to a ultra-thin film of 20 nm thickness including the mixture of the amorphous layer and the nano-microcrystal layer. This is consistent with the measurements in other fields. The peaks have relatively wide half widths, meaning that diffraction in different directions reduces the XRD peaks. It is thus reasonably supposed that other phases will probably not appear.

In addition, as described above, the Ce oxide and the TiN layer hardly react at a low temperature of 400° C. For the PLD deposition of CeO₂, therefore, only the compounds of different Ce valences may be assumed to cover all substances.

XRD showed that the samples of 6RO(2), 6RO(1), 6RO(0), 6RO(−1), and 6RO(−2) showed almost only small changes at the (002) peak position. By extrapolating the results used in the experiment example 5, the value of z in CeO_{z} for the samples was 1.93, 1.92, 1.91, 1.90, and 1.90, respectively.

A Pt electrode was deposited on each sample surface. Each surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

Every sample showed the sufficient maximum number of switchings over 50000. It is considered that the samples were not strongly affected by the oxygen partial pressure during deposition.

As in the above experimental examples, the high-resolution TEM was used to observe the structure. The results showed that the samples of 6RO(2), 6RO(1), 6RO(0), 6RO(−1), and 6RO(−2) had no large differences between their z values and 80% of the nano-microcrystals had z values of 1.84 to 1.93.

Thus, the experiment examples 5 and 6 showed that in CeO_{z}, which is a resistive recording material used in the information recording device according to the present invention, only a specific value of z improved the number of switchings. The results showed that the region included 1.50≦z≦1.98 for the nano regions. It was also shown that thin films including nano-microcrystals having an oxygen number in this region may particularly provide an excellent number of switchings.

In addition, the present invention largely improves the switching characteristics of the resistive recording material CeO_{z} having 1.70≦z≦1.95 as the entire film composition. A device that may be stably switched may thus be provided.

With respect to the CeO_{z} layer, it often has a different lanthanoid element mixed therein within one atom %, because Ce is a lanthanoid element. A thin film including the substitute substance did not show, however, a largely different switching characteristics.

### Experiment Example 7

Resistive materials were deposited on a electrically conductive substrate that includes a Si single crystal substrate and W and TiN layers deposited thereon. The substrate had a diameter of two inches and a thickness of 0.50 mm. The substrate surface was polished by the chemical and mechanical polishing process to provide RMS of 0.5 nm or less as an in-plane roughness in one micron diameter square.

The resistive layer (recording layer) was deposited by the pulse laser deposition (PLD). The targets for deposition were formed by the general sintering process. The target of ZrO₂ was used.

The ZrO₂ target was used. A substrate with TiN/W/Si layers deposited thereon was heated at 200, 300, 400, 500, and 600° C. in a vacuum chamber. A film was then deposited on the substrate at an oxygen pressure of 1×10E⁺⁰ Pa by the PLD process using a laser power of 130 mJ/mm². The deposition time was controlled to have a film thickness of about 20 nm. Samples having substrates with resistive materials deposited thereon were thus provided. Each resulting sample is described, for example, for a film provided on a substrate heated at 200° C., as 7RPT(200) (which means an ReRAM material in the experiment example 7, in the pre-state, with a temperature of 200° C.).

All of the samples were placed again in the vacuum chamber. A Pt layer was sputtered on top of each sample with a mask thereon to deposit a cylindrical Pt pad having a diameter of 50 micron. The resulting sample is described, for example, as 7RT(200) for a film with a Pt pad derived from 7RPT(200).

The high-resolution TEM was used to analyze the oxygen deficiency amount of the 7RT(600) sample. The measured amount and the peak shifts in the XRD measurement were used to calculate the amount of bound oxygen. The examples of 7RT(200), 7RT(300), 7RT(400), 7RT(500), and 7RT(600) showed 1.99, 1.97, 1.92, 1.85, and 1.79, respectively. The results showed more oxygen deficient at higher temperatures.

A Pt electrode was deposited on each sample surface. Each surface was cut to expose a small area where a probe was electrically contacted with the TiN layer. Another probe was electrically contacted with the Pt pad. Switchings were thus tested for the ReRAM device.

Using Pt as the positive electrode and TiN as the negative electrode, a voltage up to 3 V was applied across the electrodes to flow a current through the device. Switchings were done to keep an average potential difference of 1 V or more between switching on and off for a hundred switchings. Switchings up to 50000 were tested for each sample.

The samples of 7RT(400), 7RT(500), and 7RT(600) showed the maximum number of switchings over 50000. The samples of 7RT(200) and 7RT(300) showed less number of switchings and slightly unstable operations.

Thus, the experiment examples 7 showed that in ZrO_{z} film, which is a resistive recording material used in the information recording device according to the present invention, some values of z improved the switching characteristics. The results showed that the resistive recording material having 1.79≦z≦1.92 as the entire film composition may provide good switching characteristics.

Thus, the information recording device according to the present invention improves the switching characteristics by using the ZnₓMn₃₋ₓO_{z} system in the region where ZnO or the like does not undergo the phase separation, or by using Mn₃O_{z}, CeO_{z}, and ZrOz or the like at a value of z specific to each substance. Each sample showed good characteristics in a region where z moves towards more oxygen deficiency.

Although the switching principle is not completely understood, it is likely that the resistance is decreased because the oxygen deficiency provides more electron movements than those in insulators, thus increasing the electrical conductivity, and the electrical conductivity is improved in the region where the nano-microcrystals are observed by XRD so the oxides are electrically coupled, in other words, the electrical conductivity is increased by the oxygen deficiency. Although the mechanism providing the oxygen deficiency needs to be experimentally verified, at least the switching mechanism is inferred by the series of experimental results.

At reset, a large current about 1000 times larger than at set flows and almost the same voltage is applied. It is thus expected that large amount of heat about 1000 times larger occurs. Due to the heat, the metal having oxygen deficiency may return to the original stable state by absorbing oxygen in the peripheral portions and undergoing oxidation.

Assuming this, the present invention may provide a switching device capable of stable operation, although the switching principle is not completely known.

1. An information recording device comprising:
a pair of electrodes; and
a recording layer between the electrodes, the recording layer recording information by its resistance change,
the recording layer comprising at least one of (a) M₃O_{z} and (b) AₓM₃₋ₓO_{z} as a main component,
in (a) and (b), z satisfying 3.35≦z≦4.41 for 80% or more of a crystal of the composition, and
in (b), x satisfying 0.00≦x≦0.03.

2. An information recording device comprising:
a pair of electrodes; and
a recording layer between the electrodes, the recording layer recording information by its resistance change,
the recording layer comprising at least one of AₓM_{3-z}O_{z} as a main component,
z satisfying 3.35≦z≦4.41 for 80% or more of a crystal of the composition, and
x satisfying 0.15≦x≦0.90.

3. An information recording device comprising:
a pair of electrodes; and
a recording layer between the electrodes, the recording layer recording information by its resistance change,
the recording layer comprising at least one of (a) M₃O_{z} and (b) AₓM₃₋ₓO_{z} as a main component,
in (a) and (b), z satisfying 3.65≦z≦4.20 as an average of the entire recording layer, and
in (b), x satisfying 0.00≦x≦0.03.

4. An information recording device comprising:
a pair of electrodes; and
a recording layer between the electrodes, the recording layer recording information by its resistance change,
the recording layer comprising at least one of AₓM₃₋ₓO_{z} as a main component,
z satisfying 3.65≦z≦4.20 as an average of the entire recording layer, and
x satisfying 0.15≦x≦0.90.

5. The information recording device according to claim 1, wherein
A contains at least one of Zn, Cd, and Hg.

6. (canceled)

7. The information recording device according to claim 1, wherein
M contains at least one of Cr, Mn, Fe, Co, and Ni.

8. (canceled)

9. An information recording device comprising:
a pair of electrodes; and
a recording layer between the electrodes, the recording layer recording information by its resistance change,
the recording layer comprising at least one of (a) MO_{z} and (b) B_{y}M_{1-y}O_{z} as a main component,
in (a) and (b), z satisfying 1.50≦z≦1.98 for 80% or more of a crystal of the composition, and
in (b), y satisfying, 0.00≦y≦0.03.

10. An information recording device comprising:
a pair of electrodes; and
a recording layer between the electrodes, the recording layer recording information by its resistance change,
the recording layer comprising at least one (a) MO_{z} and (b) B_{y}M_{1-y}O_{z} as a main component,
in (a) and (b), z satisfying 1.70≦z≦1.95 as an average of the entire recording layer, and
in (b), y satisfying 0.00≦y≦0.03.

11. The information recording device according to claim 9, wherein
M contains Ce.

12. The information recording device according to claim 9, wherein
M contains at least one of Zr and Ti.

13. The information recording device according to claim 9, wherein
B contains at least one of Sc, Y, and lanthanoid elements except Ce.

14. An information recording/reproduction system comprising the information recording device according to claim 1.

15. The information recording device according to claim 2, wherein
A contains at least one of Zn, Cd, and Hg.

16. The information recording device according to claim 3, wherein
A contains at least one of Zn, Cd, and Hg.

17. The information recording device according to claim 4, wherein
A contains at least one of Zn, Cd, and Hg.

18. The information recording device according to claim 2, wherein
M contains at least one of Cr, Mn, Fe, Co, and Ni.

19. The information recording device according to claim 3, wherein
M contains at least one of Cr, Mn, Fe, Co, and Ni.

20. The information recording device according to claim 4, wherein
M contains at least one of Cr, Mn, Fe, Co, and Ni.

21. The information recording device according to claim 10, wherein
M contains Ce.

22. The information recording device according to claim 10, wherein
M contains at least one of Zr and Ti.

23. The information recording device according to claim 10, wherein
B contains at least one of Sc, Y, and lanthanoid elements except Ce.
